(19) United States
(12) Patent Application Publication
(10) Pub. No.: US 2023/0156932 A1
(43) Pub. Date: May 18, 2023

(54) Optical Communication Element

(71) Applicant: Nippon Telegraph and Telephone Corporation, Tokyo (JP)

(72) Inventors: Ken Tsuzuki, Musashino-shi, Tokyo (JP); Kiyofumi Kikuchi, Musashino-shi, Tokyo (JP); Yuriko Kawamura, Musashino-shi, Tokyo (JP)

(21) Appl. No.: 17/768,709

(22) PCT Filed: Oct. 17, 2019
(86) PCT No.: PCT/JP2019/040986

§ 371 Date: Apr. 13, 2022

(51) Int. Cl. H05K 5/00; H05K 1/02; H05K 9/00; H04B 10/80

(52) U.S. Cl. CPC H05K 5/0047; H05K 1/0237; H05K 9/006; H04B 10/80

(57) ABSTRACT

A COSA as an optical communication component that can prevent energy radiated in a package from causing performance degradation includes a DC block capacitor that is mounted on an upper surface of the package and located at a position different from those of a SiP chip and an optical modulator driver IC to cut off a DC signal included in a RF signal to be transmitted to the IC and a lid provided over an upper portion of the package. A separation projecting portion of the lid projecting toward an upper surface of the package separately defines a region where the capacitor is present and a region where the SiP chip and the IC are present. The separation projecting portion is connected to GND of the package, and the lid is at a GND potential.

### TECHNICAL FIELD

The present invention relates to a highly functional optical communication component having a structure in which an optical communication element and an electronic circuit element are integrated.

### BACKGROUND ART

In recent years, in optical communication technology for an optical communication system, an optical information processing system, and the like, due to explosive prevalence of a mobile terminal represented by a smartphone, enriched video delivery service, and the like, a demand for an increased transmission capacity of an optical network has grown day by day. To respond to the demand, a further technical development is in demand. To meet the demand, an optical communication system using signal processing in an electric stage such as, e.g., digital coherent communication, an ultra-high-speed communication system featuring a transmission capacity over 100 Gbit/s, and the like have been practically implemented.

In addition, it is technically important to achieve a size reduction and a cost reduction for each of optical communication components used in these systems. In such an optical communication component, an optical communication element and an electronic circuit element are used in most cases as a set. An optical modulator serving as an example of the optical communication element outputs either of an intensity-modulated signal obtained by modulating an intensity of an optical signal incident thereon and a phase-modulated signal obtained by modulating a phase of light. An optical modulator driver integrated circuit (hereinafter referred to as an optical modulator driver IC) serving as an example of the electronic circuit element changes either of the intensity-modulated signal and the phase-modulated signal each from the optical modulator to an optical signal that can be processed in the electric stage and then outputs the optical signal. A light receiving element serving as another example of the optical communication element receives an optical signal transmitted thereto, converts the optical signal to an electric signal, and then outputs the electric signal. A transimpedance amplifier (hereinafter referred to as the TIA) serving as another example of the electronic circuit element amplifies and processes the electric signal from the light receiving element such that the electric signal can be processed in the electric stage.

By the way, to implement a compact and low-cost optical communication component that handles a high-speed signal, the optical communication element and the electronic circuit element are mostly mounted in one package to be configured as an optical communication component. This is because, by integrating the individual devices with each other, it is possible to prevent attenuation and reflection of an electric signal between the devices and also reduce connected portions of wires. This serves as a contribution to prevention of a degraded electrical characteristic and to achievement of a size reduction and a cost reduction.

As an example of such an optical communication component, an integrated coherent receiver (hereinafter abbreviated as the ICR) that receives an optical signal by digital coherent communication can be listed. The ICR is an optical communication component in which an optical circuit that separates optical signals resulting from multi-value phase modulation by respective phases thereof, a light receiving element that converts the optical signals to electricity, a TIA that amplifies electric signals, and the like are mounted in one package.

In the ICR, each of the electric signals output from the TIA is retrieved from the package to the outside thereof via RF wiring. However, when a direct-current (hereinafter abbreviated as DC) voltage is applied from an external electronic circuit element to the ICR, an electronic circuit element such as the TIA may break down. Accordingly, a capacitor component referred to as a DC block that allows a high-frequency signal to pass therethrough, but does not allow the DC signal to pass therethrough is needed on the RF wiring. Note that, in the ICR, it is typical to embed even the DC block in the package. The high-frequency signal, which is in a short wavelength band including a versatile radio frequency (RF), is hereinafter referred to as the RF signal.

The DC block is made of a chip capacitor disposed on the RF wiring and has a property of allowing RF signals having frequencies ranging from several megahertz in a low frequency band to several tens of gigahertz in a high-frequency band to pass therethrough and not allowing the DC signal of up to kHz order to pass therethrough. For the DC block embedded in an optical communication component such as the ICR, a structure in which a chip capacitor of a size of about 0.6×0.3 mm or 0.4×0.2 mm is disposed on RF wiring having a width of about 100 μm is used. Accordingly, to a portion corresponding to the DC block, layout consideration is preferably given by increasing the width of the RF wiring or locating a ground (hereinafter abbreviated as GND) electrode at a long distance therefrom such that a characteristic impedance is controlled not to greatly vary compared to that in a portion corresponding to the RF wiring. However, when such control is performed, it is required to reduce reflection, radiation, and the like of the RF signals.

FIG. 1 is an outer appearance perspective view when viewed from obliquely above in which a structural shape of a DC block in a package 11 in an ICR 10 as a known optical communication component is partially broken and exposed. Note that the ICR 10 typically has a function of receiving polarization-multiplexed signals having two phase components perpendicular to each other and outputting four pairs of differential electric signals.

Referring to FIG. 1, the package 11 of the ICR 10 is preferably made of a ceramic and has, as a base, a pedestal structure in which a recessed portion for mounting the component is formed in a frame-shaped erecting wall portion. On a flat surface of the recessed portion of the package 11, the DC block including a pair of two RF wires 12 that transmit differential electric signals and DC block capacitors 14 is provided. The RF wires 12 include grounded coplanar lines circumferentially surrounded by GND electrodes 13 to receive an output signal from a TIA input thereto and output the pair of differential electric signals. The DC block capacitors 14 connected to the RF wires 12 allow the output signal from the TIA transmitted through the RF wires 12 to pass therethrough and cut off a DC signal when the DC signal is included in the output signal.

In the ICR 10, the output signal from the TIA is transmitted through the RF wires 12 and passes through the DC block capacitors 14. A portion of the package 11 located below the flat surface of the recessed portion thereof serves as a laminated ceramic package 11a formed by alternately laminating ceramic layers and metal layers. The output signal after the DC signal is cut off is transmitted to the lower layers via metal via wires placed to extend through the ceramic layers in the laminated ceramic package 11a. The output signal is further led out from signal output lead wires 15 formed to be exposed on a rear side of the laminated ceramic package 11a.

In the case of the ICR 10, a potential of a signal line of the external electronic circuit may not be the same as the GND potential and, at this time, a DC voltage is applied to each of the lead wires 15 serving as signal lines. When the voltage of the lead wire 15 at this time is applied directly to the TIA via the RF wires 12, a withstand voltage of a semiconductor forming the TIA may be exceeded, and consequently the DC block is required to protect the electronic circuit of the TIA.

FIG. 2 is a partially enlarged view illustrating a result of simulating an electric field intensity of the RF signal in the package 11 of the ICR 10 illustrated in FIG. 1. Specifically, in FIG. 2, the electric field intensity of the RF signal in a portion of the package 11 where the RF wires 12 for outputting the two pairs of differential electric signals and the total of four DC block capacitors 14a and 14b included in two pairs are present is illustrated.

Referring to FIG. 2, the output signal from the TIA is transmitted through the RF wires 12 and passes through the DC block capacitors 14a and 14b. It can be seen that, at the time of the passage, the electric field intensity is higher in regions E1 and E2 before the DC block capacitors 14a and 14b. Note that the electric field intensity indicates reflection of the RF signal, radiation thereof to the outside, and the like. Such reflection, radiation, and the like are caused by mismatched characteristic impedances, mismatched propagation modes of the RF signal, and the like. From a result of more detailed analysis, it was found that the higher electric field intensities represented returning of energy of the RF signal radiated in the package 11 as noise at an unintended place. In such a case, the returning of the RF signal as the noise serves as a factor causing degradation of performance of the optical communication component.

To prevent performance degradation due to the reflection of the RF signal in such a DC block portion, radiation thereof to the outside, and the like, it is necessary to adjust the respective characteristic impedances of a portion corresponding to the RF wires 12 and the DC block portion. It may also be possible to achieve a match between RF propagation mode shapes or the like, but either the characteristic impedance adjustment or the match achievement needs to be performed carefully.

For example, to achieve connection to each of the RF wires 12 having a width of about 100 μm, a compact chip capacitor having not a 0.6×0.3 mm size, but a 0.4×0.2 mm size is used. In addition, by using a technique of reducing a gap between the signal line of each of the RF wires 12 and the GND electrode 13 or reducing a size difference when the propagation mode is converted, it is possible to prevent the performance degradation to a given degree.

However, the RF signal transmitted by each of the RF wires 12 formed on flat surfaces of the grounded coplanar lines and the RF signal passing through the chip capacitor having a height differ in propagation mode shape. Specifically, compared to the RF wire 12 on a flat surface having a width of about 100 μm, the 0.6×0.3 mm chip capacitor has a height as large as 0.3 mm, and accordingly the RF signal passing through the chip capacitor is transformed into a propagation mode having an extent which is about three times as wide as and about three to five times as high as that of a propagation mode of the RF signal transmitted by the RF wire 12. As a result, even when the characteristic impedances adjustment is carefully performed, the chip capacitor results in a place where a certain degree of reflection of the RF signal, a certain degree of radiation thereof to the outside, and the like occur.

When the reflection of the RF signal thus occurs in the DC block portion, signal quality degradation such as attenuation of the output signal and a reduction in an output amplitude at a specified frequency occurs. Meanwhile, when the radiation of the RF signal to the outside occurs in the DC block portion, the RF noise may expand in an inner space of the optical communication component and begin to turn back to the RF signal at an unexpected place. In addition, the radiation of the RF signal to the outside may result in amplification of the RF signal by the optical modulator driver IC and the TIA, oscillation thereof, and the like and lead to significant performance degradation of the optical communication component.

Due to such circumstances, it is difficult to completely eliminate reflection and radiation between the flat RF wires 12 and the chip capacitors each having a given height. Accordingly, a coping method such as placement of a radio wave absorber for absorbing the high-frequency energy radiated in the space in the optical communication component may occasionally be used. The radio wave absorber comes in a type that absorbs an electric current generated by a radio wave by using an inner resistance of a material, a type that uses a dielectric loss, a type that uses a magnetic loss in a magnetic material such as ferrite, or the like. The radio wave absorber of any type absorbs the high-frequency energy radiated in the inner space of the package 11 and prevents returning of the energy to be able to achieve an effect of noise reduction, oscillation prevention, or the like.

However, when the radio wave absorber is used, setting of a layout presents a problem. For example, when the radio wave absorber is present immediately above the RF wires 12, the radio wave absorber undesirably serves as a factor which attenuates the RF signal. In addition, when the radio wave absorber is fixed in the package 11 also, an actual method encounters difficulty. Moreover, an application of the radio wave absorber is difficult unless the radio wave absorber satisfies conditions that a material thereof can efficiently absorb a radio wave and there is no large difference between a thermal expansion coefficient thereof and that of each of constituent elements in the package 11.

Specifically, unless it is guaranteed that the radio wave absorber drops off within a temperature range of −5° C. to 85° C. corresponding to an operating temperature of the optical communication component, it becomes difficult to use the radio wave absorber over a long period of time. Besides, no generation of a gas that may affect the optical communication component, no long-term quality deterioration, and the like is also required. This results in a situation where use of an extra radio wave absorber as a countermeasure against performance degradation increases the number of component parts, leads to a detriment to a cost reduction, and is therefore hard to practically implement.

There are another configuration of an optical communication component in which an optical communication element and an electronic circuit element are mounted in one package. Specifically, as another example, a coherent optical sub-assembly (hereinafter abbreviated as COSA) using silicon photonics technology can be listed. The COSA has a silicon photonics chip (hereinafter referred to as the SiP chip) in which an optical circuit, an optical modulator, a germanium optical receiver, and the like are integrated in one chip by using the silicon photonics technology of forming an optical element on a silicon substrate. Then, the SiP chip serving as an optical communication element and an optical modulator driver IC and a TIA each serving as an electronic circuit element are contained together in one package to allow the COSA to be configured as the optical communication component. In the COSA also, for the protection of the optical modulator driver IC and the TIA, a DC block is embedded in the package.

FIG. 3 is a diagram illustrating a cross section of an example of a basic structure of a COSA 20 as a known optical communication component in a side surface direction.

Referring to FIG. 3, a package (PKG) 21 of the COSA 20 is preferably made of a ceramic or of an organic substrate material, and has a base having a flat plate shape. An upper portion of the package 21 is covered with a lid (LID) 27 for protecting various devices such as an optical modulator driver IC 26, a SiP chip 25, and DC block capacitors 24a and 24b each mounted on an upper surface of the package 21. On a lower surface of the package 21, a solder BGA (Ball Grid Array) 31 for effecting connection and fixation to a printed circuit board (PCB) as a connection partner is juxtaposed. The optical modulator driver IC 26 and the SiP chip 25 are connected and fixed by individual Au bumps 32 provided in juxtaposition to a conductive pattern on the upper surface of the package 21.

The conductive pattern provided on the package 21 includes RF wires, GND electrodes, metal via wires, and the like. To the package 21 of the COSA 20 also, a laminated ceramic structure can be applied. For example, it is possible to provide connection between the various devices with the RF wires and place the metal via wires for routing and connection of the inner-layer GND electrode. However, a detailed configuration of the conductive pattern is not specified herein except that the DC block capacitor 24a is interposed between the RF wires to be able to protect the optical modulator driver IC 26 serving as the electric circuit element.

Preferably, the lid 27 is formed of a metal material having a high thermal conductivity such as aluminum or a copper alloy and the like. In such a case, devices such as the optical modulator driver IC 26 and the TIA generate heat during operation thereof, and accordingly a heat dissipation structure is used as countermeasures against heat generation. In the example illustrated in FIG. 3, a heat dissipation paste 28 is interposed between a projecting portion 27a corresponding to an inner projecting portion of the lid 27 and an upper surface of the optical modulator driver IC 26. Since the lid 27 is bonded to the package 21, the heat dissipation paste 28 may be applied appropriately to, e.g., the inner projecting portion 27a of the lid 27. This can provide a structure in which heat generated from the optical modulator driver IC 26 is transferred to the lid 27 via the heat dissipation paste 28 present on the upper surface of the optical modulator driver IC 26 to be dissipated.

An exemplary case can be illustrated in which, as a material of the package 21, a low-temperature co-fired ceramic (hereinafter abbreviated as LTCC) as a type of ceramic is used. The LTCC in use has a thermal expansion coefficient of about 11 ppm/K close to that of the printed circuit board to be connected to the package 21 via the solder BGA 31, and is excellent in terms of mountability of the optical communication component. Note that, when aluminum is used as a metal material to be used for the lid 27, the lid 27 has a thermal expansion coefficient of about 23 ppm/K and, when a copper alloy is used as the metal material to be used for the lid 27, the lid 27 has a thermal expansion coefficient of about 17 ppm/K.

It is said that, unlike an optical element formed of an indium phosphide InP material or the like, the COSA 20 does not require hermetic sealing, and a non-airtight package structure that can easily be produced at low cost is used. Of the non-airtight package structure, a portion corresponding to the package 21 based on ceramic or the like and a portion corresponding to the lid 27 can be bonded together by an easy method using an adhesive or the like, not by a bonding method such as silver brazing or welding. When a copper alloy having a relatively small thermal expansion coefficient difference with the LTCC is used as the metal material to be used for the lid 27, cost is slightly higher than when aluminum is used as the metal material of the lid 27. When lower-cost aluminum is used as the metal material of the lid 27, a problem to be solved is how to overcome a thermal expansion coefficient difference with the LTCC.

In the COSA 20 having the non-airtight package structure illustrated in FIG. 3, as the countermeasures against heat generation, the heat dissipation paste 28 is interposed between the local inner projecting portion 27a of the lid 27 and the upper surface of the optical modulator driver IC 26 to improve heat dissipation efficiency. However, with such a mere inventive modification, even though a heat dissipating effect is obtained during heat generation from the devices in the package 21, a problem that energy radiated at an unintended place in the package 21 returns as noise to result in performance degradation cannot be solved.

Note that, as a known technique related to an optical communication component having an integrated structure, a form of the COSA is shown in NPL 1. The COSA is configured by flip-chip mounting a SIP chip, a driver IC, and a TIA on a package made of an LTCC material and disposing chip capacitors serving as DC blocks on the package. In addition, in the same manner as in the case described with reference to FIG. 3, the COSA is configured by covering an upper portion of the entire package with a lid. Meanwhile, in NPL 2, as an example of an optical communication element, an InP-based 90⁰ hybrid integrated light receiving element for 100 Gbit/s compact coherent receivers is disclosed.

### CITATION LIST

### Non Patent Literature

[NPL 1] C. Doerr, J. Heanue, L. Chen, R. Aroca, S. Azemati, G. Ali, G. McBrien, Li Chen, B. Guan, H. Zhang, X. Zhang, T. Nielsen, H. Mezghani, M. Mihnev, C. Yung, and M. Xu “Silicon Photonics Coherent Transceiver in a Ball-Grid Array Package”, 2017 Optical Fiber Communications Conference and Exhibition (OFC), March 2017, Post-Deadline paper, Th5D. 5.
[NPL 2] N. Inoue, H. Yagi, R. Masuyama, T. Katsuyama, Y. Yoneda, and H. Shoji, “InP-Based Photodetector Monolithically Integrated with 90° Hybrid for 100 Gbit/s Compact Coherent Receivers”, SEI Technical Review No. 185, July 2014, pp. 61-66.

### SUMMARY OF THE INVENTION

Embodiments according to the present invention are achieved in order to solve the problems described above. An object of the embodiments according to the present invention is to provide an optical communication component capable of preventing energy radiated at an intended place in a package from returning as noise and causing performance degradation.

To attain the object described above, an aspect of the present invention is an optical communication component including: a package having a flat plate shape; an optical communication element mounted on an upper surface of the package; an electronic circuit element mounted on the upper surface of the package and located at a position different from that of the optical communication element; a DC block device mounted on the upper surface of the package and located at a position different from those of the optical communication element and the electronic circuit element to cut off a DC signal included in a RF signal transmitted to the electronic circuit element via a conductive pattern provided on the package; and a lid provided over an upper portion of the package to cover the optical communication element, the electronic circuit element, and the DC block device, the lid having a separation projecting portion that projects toward the upper portion of the package to separately define a region where the DC block device is present and a region where the optical communication element and the electronic circuit element are present.

The optical communication component having the configuration described above can prevent energy radiated at an intended place in a package from returning as noise and causing performance degradation.

### BRIEF DESCRIPTION OF DRAWINGS

FIG. 1 is an outer appearance perspective view when viewed from obliquely above in which a structural shape of a DC block in a package in an ICR as a known optical communication component is partially broken and exposed.

FIG. 2 is a partially enlarged view illustrating a result of simulating an electric field intensity of an RF signal in the package of the ICR illustrated in FIG. 1.

FIG. 3 is a diagram illustrating a cross section of an example of a basic structure of a COSA as a known optical communication component in a side surface direction.

FIG. 4 is a diagram illustrating a cross section of a basic structure of a COSA as an optical communication component according to a first embodiment of the present invention in the side surface direction.

FIG. 5 is a diagram illustrating a cross section of another example of a basic structure of a COSA as an optical communication component according to a comparative example in the side surface direction.

FIG. 6 is a diagram illustrating a cross section of a basic structure of a COSA as an optical communication component according to a second embodiment of the present invention in the side surface direction.

FIG. 7 is a cross-sectional view illustrating a partially broken conductive pattern of a grounded coplanar line including RF wires placed in a surface layer and GND electrodes disposed in an inner layer and in the surface layer, which is applicable to a package related to a principal portion of the COSA illustrated in FIG. 5.

FIG. 8 is a perspective view of a conductive pattern on the package illustrated in FIG. 7, which is partially illustrated in a cross section.

FIG. 9 is a cross-sectional view illustrating a partially broken conductive pattern including RF wires placed in an inner layer and GND electrodes disposed in the inner layer and in a surface layer, which is applicable to a package related to a principal portion of the COSA illustrated in FIG. 6.

### DESCRIPTION OF EMBODIMENTS

Referring to the drawings, a detailed description will be given of an optical communication component according to each of embodiments of the present invention.

### First Embodiment

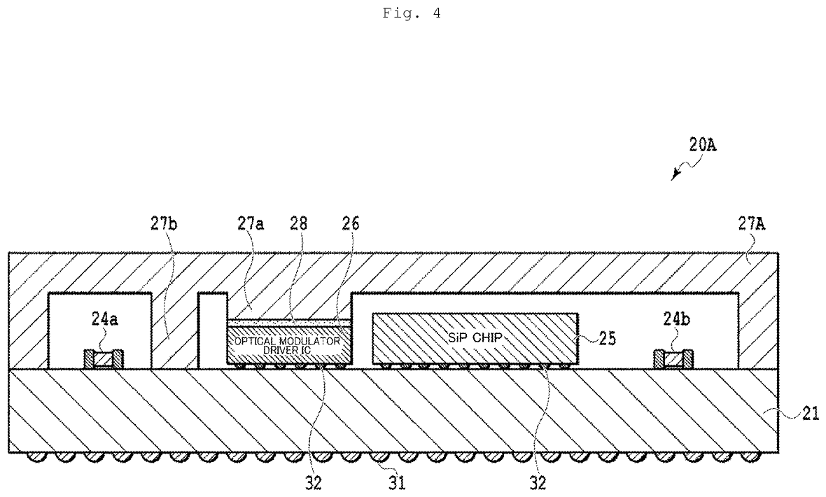

FIG. 4 is a diagram illustrating a cross section of a basic structure of a COSA 20A as an optical communication component according to the first embodiment of the present invention in a side surface direction.

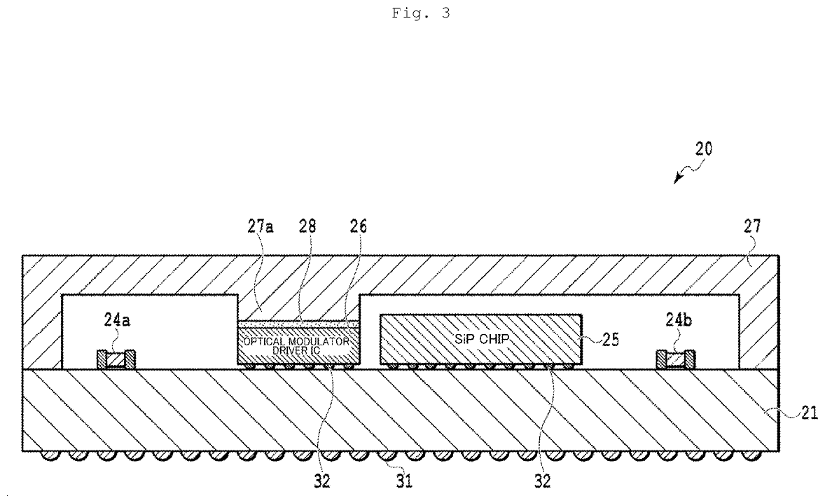

Referring to FIG. 4, the COSA 20A is similar to the COSA 20 in FIG. 3 in that a lid 27A has the projecting portion 27a and different from the COSA 20 in FIG. 3 in having a separation projecting portion 27b projecting toward the upper surface of the package 21 having the flat plate shape. The separation projecting portion 27b has a function of separately defining a region where the DC block capacitor 24a is present and a region where the SiP chip 25 serving as the optical communication element and the optical modulator driver IC 26 serving as the electronic circuit element are present.

The DC block capacitors 24a and 24b also cut off herein the DC signal included in the RF signal transmitted to the optical modulator driver IC 26, the TIA, and the like via the conductive pattern provided on the package 21. The conductive pattern may also be regarded as including the RF wires and the GND electrodes. This allows the DC block capacitors 24a and 24b to function as DC block devices protecting the various devices.

A one portion of the GND electrodes of the conductive pattern is electrically connected to a tip surface of the separation projecting portion 27b of the lid 27A. When a state of the connection is mechanically stable, sufficient contact is provided between the GND electrode and the tip surface of the separation projecting portion 27b. When the state of the connection is not mechanically stable, the GND electrode of the conductive pattern mentioned above and the tip surface of the separation projecting portion 27b mentioned above may also be bonded together using an adhesive or the like. However, when, e.g., a non-conductive adhesive is used as the adhesive, side walls of the separation projecting portion 27b in the vicinity of the tip surface thereof may be adhesively fixed appropriately to a top surface of the package 21 by using the adhesive so as to prevent the adhesive from being applied to the tip surface of the separation projecting portion 27b. Meanwhile, when a conductive adhesive is used as the adhesive, the tip surface of the separation projecting portion 27b may be adhesively fixed appropriately to the surface of the package 21 by using the adhesive. In either case, mechanical stability as well as an electrically connected state is maintained. When conduction is provided between the GND electrode and the tip surface of the separation projecting portion 27b of the lid 27A, the lid 27A is at a GND potential. Alternatively, the electrical connection between the lid 27A and the package 21 may also be provided not at the separation projecting portion 27b, but at another region such as an outer peripheral edge portion. In such a case, since the RF wires are placed on the surface of the package 21 to be brought into contact with the separation projecting portion 27b, when the lid 27A at the GND potential is brought closer thereto, it is required to give sufficient consideration so as not to affect a RF characteristic.

Note that, to the package 21 of the COSA 20A also, the laminated ceramic structure can be applied. For example, it is possible to connect the various devices with the RF wires included in the conductive pattern and place the metal via wires for routing and connection of the inner-layer GND electrode. However, it is also assumed that a detailed configuration of the conductive pattern is not specified herein except that the DC block capacitor 24a is interposed between the RF wires to be able to protect the optical modulator driver IC 26 serving as the electric circuit element.

The configuration is otherwise the same as in the case of the COSA 20. Specifically, the SiP chip 25 is configured by integrating an optical circuit, an optical modulator, a germanium optical receiver, and the like in one chip by using the silicon photonics technology of forming an optical element on a silicon substrate. An upper portion of the package 21 is covered with the lid 27A for protecting devices such as the optical modulator driver IC 26, the SiP chip 25, and the DC block capacitors 24a and 24b each mounted on the upper surface of the package 21. On the lower surface of the package 21, the solder BGA 31 for effecting connection and fixation to the printed circuit board as the connection partner is juxtaposed. The optical modulator driver IC 26 and the SiP chip 25 are connected and fixed by the individual Au bumps 32 provided in juxtaposition to the conductive pattern on the upper surface of the package 21.

Preferably, the lid 27A is formed of a metal material having a high thermal conductivity such as aluminum or a copper alloy and the like. Devices such as the optical modulator driver IC 26 and the TIA also generate heat during operation thereof, and accordingly a heat dissipation structure is used herein as countermeasures against heat generation. Specifically, the structure is such that the heat dissipation paste 28 is interposed between the projecting portion 27a corresponding to the inner projecting portion of the lid 27A and the upper surface of the optical modulator driver IC 26. Since the lid 27A used herein is also bonded to the package 21, the heat dissipation paste 28 may be applied appropriately to the inner projecting portion 27a of the lid 27A. This can provide a structure in which the heat generated from the optical modulator driver IC 26 is transferred to the lid 27A via the heat dissipation paste 28 present on the upper surface of the optical modulator driver IC 26 to be dissipated.

In the case of the COSA 20A according to the first embodiment, on the inner side of the lid 27A, the separation projecting portion 27b as well as the projecting portion 27a for using the heat dissipation paste 28 is provided. The separation projecting portion 27b separately defines the region where the DC block capacitor 24a is present and the region where the electronic circuit element is present. Consequently, the energy of the RF signal reflected by the portion corresponding to the DC block and radiated in the inner space of the package 21 is confined to a space formed by inner walls of the lid 27A and the top surface of the package 21. As a result, it is possible to sufficiently prevent the energy radiated at an unintended place in the package 21 from returning as noise and causing performance degradation.

Also, in the case of the COSA 20A according to the first embodiment, as the metal material of the lid 27A, a copper alloy or the like having a relatively small thermal expansion coefficient difference with the LTCC as the material of the package 21 is used preferably. In this case, it is possible to provide a compact and high-performance optical communication component that is hardly affected by thermal expansion. However, for a cost reduction, aluminum having a relatively large thermal expansion coefficient difference with the LTCC as the material of the package 21 can also be used as a metal material of the lid 27A. In such a case, due to the presence of the separation projecting portion 27b other than the projecting portion 27a, the lid 27A has an improved mechanical strength. As a result, even when aluminum is used as the metal material of the lid 27A, influence of thermal expansion is reduced, and it is possible to provide a compact and low-cost optical communication component.

Note that, in the exemplified structure of the COSA 20A according to the first embodiment, the separation projecting portion 27b separately defines the region where the DC block capacitor 24a is present. However, in the COSA 20A, the conductive pattern provided on the package 21 also differs depending on a mode of each of the various devices mounted on the upper surface of the package 21. Accordingly, it is possible to provide the COSA 20A with a structure in which an additional separation projecting portion is provided to separately define even the region where the DC block capacitor 24b is present. In other words, the number of the separation projecting portions to be disposed and places where the separation projecting portions are to be disposed can freely be changed depending on various devices mounted on the package 21 and the conductive pattern for connection thereof.

### Second Embodiment

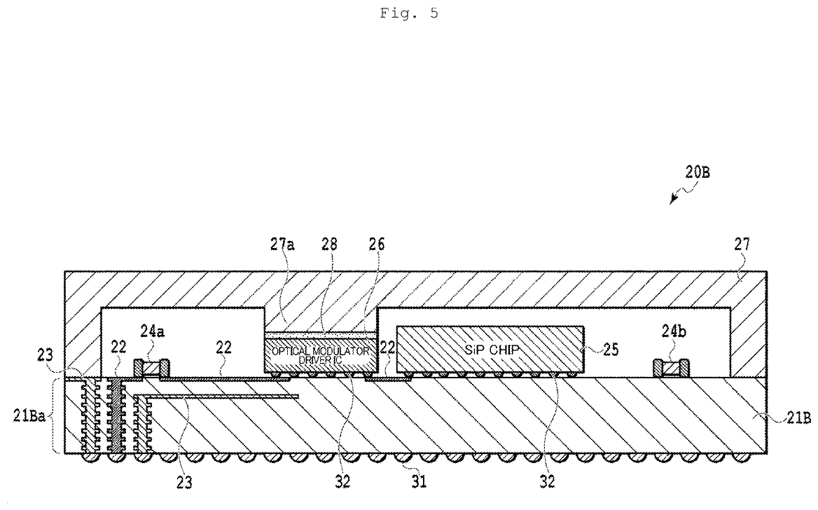

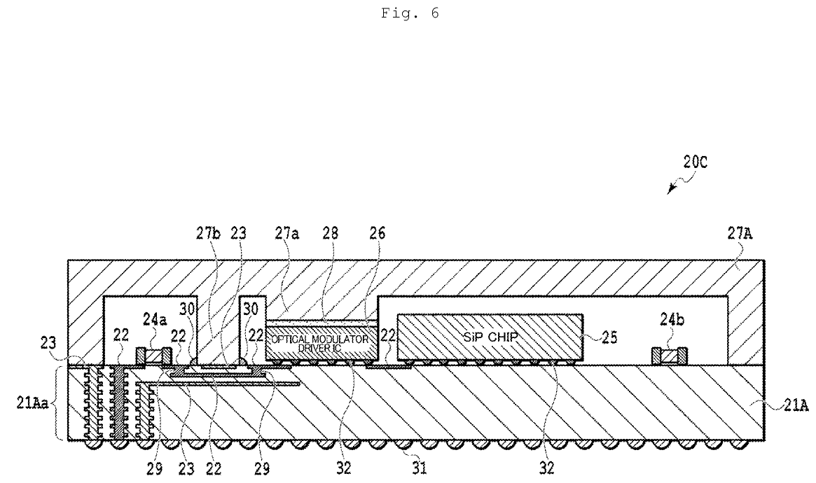

FIG. 6 is a diagram illustrating a cross section of a basic structure of a COSA 20C as an optical communication component according to the second embodiment of the present invention in the side surface direction. Note that, in the second embodiment, referring to FIG. 5 illustrating a cross section of another example of a basic structure of a COSA 20B as an optical communication component according to a comparative example, a description will be given of a difference between the respective basic structures of the COSA 20C and the COSA 20B, while consideration is given thereto.

Referring to FIG. 5, the COSA 20B according to the comparative example is different from the COSA 20 in FIG. 3 in a routing and connection structure of a conductive pattern on a package 21B having a flat plate shape. To the package 21B, a laminated ceramic package 21Ba is applied, and routing of the RF wires 22, GND electrodes 23, and metal via wires described later is performed. The RF wires 22 are placed so as to connect, as a whole, the DC block capacitor 24a, the optical modulator driver IC 26, and the SiP chip 25 such that the DC block capacitor 24a is interposed between the RF wires 22. Note that the lid 27 is merely configured to have a heat dissipation projecting portion 27a.

In the laminated ceramic package 21Ba, the metal via wire connecting the GND electrode 23 on an upper surface of the package 21B and the solder BGA 31 in a direction of lamination is applied. Note that, around the metal via wire, via wires of the GND electrode 23 are similarly illustrated. Additionally, the metal via wire connecting the RF wire 22 connected to the DC block capacitor 24a on the upper surface of the package 21B and the solder BGA 31 in the direction of lamination is also applied. Still additionally, the metal via wire connecting the inner-layer GND electrode 23 of the package 21B and the solder BGA 31 in the direction of lamination is also applied.

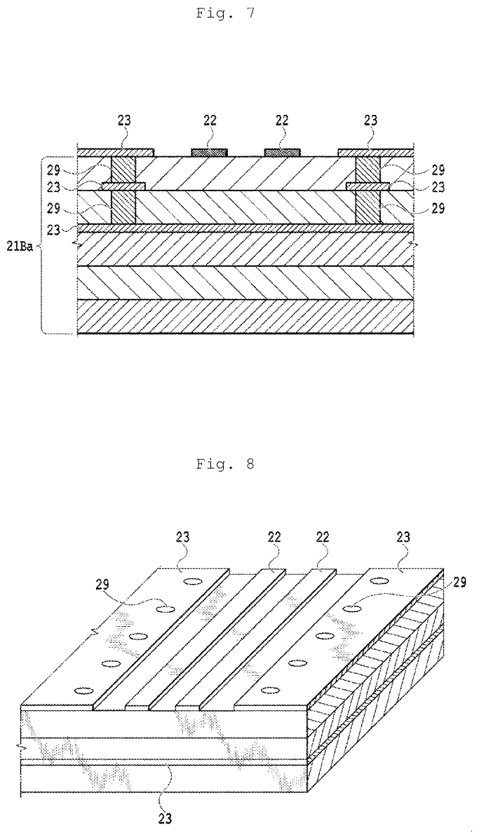

The via wires of the GND electrodes 23 are placed so as to surround the metal via wire of the RF wire 22 and, by using a structure similar to that of a coaxial line, it is possible to implement a characteristic with reduced reflection and attenuation of the PF signal. Note that the GND electrodes 23 formed in layers underlying the RF wires 22 formed on the top surface of the package 21B include the GND electrode 23 and the metal via wire in the surface layer not shown, and a layout thereof is illustrated in FIG. 7 described later.

Referring to FIG. 6, the COSA 20C is different from the COSA 20B in FIG. 5 in that a laminated ceramic package 21Aa is applied as a routing and connection structure in a conductive pattern on a package 21A having a flat plate shape. Various devices provided on an upper surface of the package 21A are the same as those used in the case of the first embodiment. The lid 27A is configured to have the projecting portion 27a and also have the separation projecting portion 27b. Note that, as illustrated in the first embodiment, as the material of the lid 27A, the metal material having the high thermal conductivity is used and, as the material of the package 21A, the LTCC material or the like having the thermal expansion coefficient closer to that of the printed circuit board as the connection partner is used.

The laminated ceramic package 21Aa has a wiring structure in which a portion of the RF wire 22 temporarily extends into the inner layer of the package 21A via one of metal via wires 29 and then returns again to the surface layer via another of the metal via wires 29 at another position. The RF wires 22 are placed so as to connect, as a whole, the DC block capacitor 24a, the optical modulator driver IC 26, and the SiP chip 25 such that the DC block capacitor 24a is interposed between the RF wires 22. Note that the GND electrodes 23 formed in the layers overlaying and underlying the RF wires 22 formed in the inner layer of the package 21A have metal via wires not shown, and a layout thereof is illustrated in FIG. 9 described later.

In the case of the COSA 20C also, the separation projecting portion 27b separately defines the region where the DC block capacitor 24a is present and the region where the electronic circuit element is present. Consequently, the energy of the RF signal reflected by the portion corresponding to the DC block and radiated in an inner space of the package 21A is confined to a space formed by the inner walls of the lid 27A and a top surface of the package 21A. As a result, it is possible to prevent the energy radiated at an unintended place in the package 21A from returning as noise and causing performance degradation.

Additionally, in the case of the COSA 20C, the portions of the RF wires 22 connecting the DC block capacitor 24a and the optical modulator driver IC 26 are placed in the inner layer of the package 21A and, in the surface layer of the inner-layer portion in which the RF wires 22 are placed, the GND electrode 23 is disposed. Such a configuration allows the tip surface of the separation projecting portion 27b of the lid 27A to come into contact with the GND electrode 23 on the upper surface of the package 21A and be electrically connected thereto without bringing the tip surface of the separation projecting portion 27b into contact with the RF wire 22.

In other words, such a form allows the space in which the DC block is provided to be provided as a closed space. Elements forming the closed space include the GND electrode 23 on the top surface of the package 21A to be connected to the tip surface of the separation projecting portion 27b of the lid 27A and inner walls of the lid 27A at the GND potential in such a state of connection. Such elements also include the GND electrode 23 formed on an end side of the top surface of the package 21A to be bonded to an end surface of an edge portion of the lid 27A.

In the COSA 20C having such a configuration, the energy of the RF signal reflected by the DC block portion and radiated in the inner space of the package 21A is confined to a space formed by the lid 27A at the GND potential and the GND electrode 23 on the upper surface of the package 21A. A confining effect achieved by the COSA 20C is more remarkable than that achieved by the COSA 20A in the first embodiment.

In other words, the COSA 20C in the second embodiment achieves the same actions and effects as those achieved by the COSA 20A in the first embodiment and can more reliably prevent occurrence of performance degradation. As a result, it is possible to provide a compact and low-cost optical communication component having an excellent RF characteristic. In particular, in the case of the COSA 20C, the portions of the RF wires 22 are placed in the inner layer of the package 21A to allow the tip surface of the separation projecting portion 27b of the lid 27A to be connected mechanically solidly to the GND electrode 23 on the top surface of the package 21A. As a result, to maintain a connected state, bonding the side walls in the vicinity of the tip surface of the separation projecting portion 27b of the lid 27A and the top surface of the package 21A together using, e.g., the non-conductive adhesive 30 or the like is effective, as illustrated in FIG. 6. When the non-conductive adhesive 30 is used, it is preferable to prevent the adhesive 30 from being applied to the tip surface of the separation projecting portion 27b and provide conduction between the GND electrode 23 and the lid 27A through the tip surface of the separation projecting portion 27b. Meanwhile, when the conductive adhesive is used, the tip surface of the separation projecting portion 27b and the GND electrode 23 on the upper surface of the package 21A are adhesively fixed to each other by using the adhesive. In either case, it is possible to provide a form in which mechanical stability and an electrically connected state are simultaneously maintained. Alternatively, as described in the first embodiment, it is also possible to provide electrical connection between the lid 27A and the package 21 not at the separation projecting portion 27b, but at another place, and points to be considered in that case are also as described above. In this state, the lid 27A is at the GND potential.

The electronic circuit element to be used in the optical communication component comes in various types such as a type that requires heat dissipation and a type that requires a potential at a back surface thereof to be reduced to the GND potential. For example, the optical modulator driver IC 26 illustrated in each of FIGS. 3, 4, 5, and 6 is of a type that requires heat dissipation and also requires a potential at a back surface thereof to be reduced to the GND potential. This results from flip-chip mounting of the optical modulator driver IC 26 with the back surface thereof facing upward. The SiP chip 25 illustrated in each of the drawings mentioned above is also flip-chip mounted.

When consideration is given to such circumstances, there is a case where a paste for which a material having an optimal property is to be selected and which need not necessarily have a strong bonding force, such as a thermally conductive paste having an excellent heat dissipation property or a low-resistance conductive paste, may be applied. In such a point also, it can be said that the form in the second embodiment in which a bonding area can be increased to ensure a bonding strength between the lid 27A and the package 21A is advantageous. In other words, by ensuring the bonding strength between the lid 27A and the package 21A as appropriate, it is possible to use the optical communication component for a long period without separating the lid 27A from the package 21A in a range of −5° C. to 85° C. corresponding to an operating temperature of the optical communication component. In such a case, it is possible to provide the optical communication component excellent in mechanical stability and long-term reliability.

A structure in which the portions of the RF wires 22 connecting the DC block capacitor 24a and the optical modulator driver IC 26 are placed in the inner layer of the package 21A and the GND electrode 23 is disposed in the surface layer, such as that of the COSA 20C, has various advantages. This structure allows a structure in which the RF wires 22 are circumferentially surrounded by the GND electrodes 23 to be provided, which is effective in improving a characteristic compared to the grounded coplanar line applicable to a case where the RF wires 22 are on the top surface of the package 21A. In other words, by also covering the upper portions of the RF wires 22 with the GND electrodes 23, it is possible to reduce likelihood of entrance of noise from the outside and reduce radiation of the RF signal to the outside.

The following will add technical supplementary notes with respect to the laminated ceramic package 21Ba of the COSA 20B according to the comparative example described above and the laminated ceramic package 21Aa of the COSA 20C according to the second embodiment.

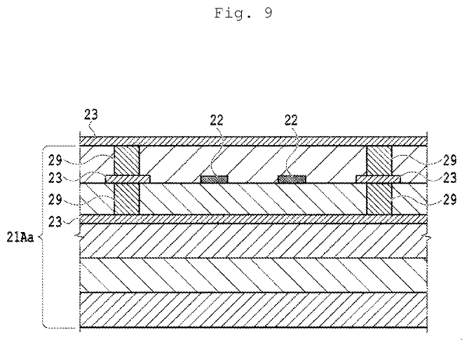

FIG. 7 is a cross-sectional view illustrating a partially broken conductive pattern applicable to the package 21B related to a principal portion of the COSA 20B according to the comparative example described above. The conductive pattern on the laminated ceramic package 21Ba is a grounded coplanar line including the RF wires 22 placed in the surface layer and the GND electrodes 23 disposed in the inner layer and in the surface layer. FIG. 8 is a perspective view of the conductive pattern on the package 21B, which is partially illustrated in a cross section. Note that, in FIG. 7, the layout of the GND electrode 23 in the surface layer and the metal via wires 29, which is not illustrated in FIG. 5, is also illustrated.

FIG. 9 is a cross-sectional view illustrating a partially broken conductive pattern applicable to the package 21A related to a principal portion of the COSA 20C according to the second embodiment described above. The conductive pattern on the laminated ceramic package 21Aa includes the RF wires 22 placed in the inner layer and the GND electrodes 23 disposed in the inner layer and in the surface layer. In other words, FIG. 9 illustrates a form in which the inner-layer RF wires 22 are surrounded by the GND electrodes 23 in the surface layer and in the inner layer and by the metal via wires 29 in the inner layers. Note that, in FIG. 9, a layout of the metal via wires 29 not illustrated in FIG. 6 is also illustrated.

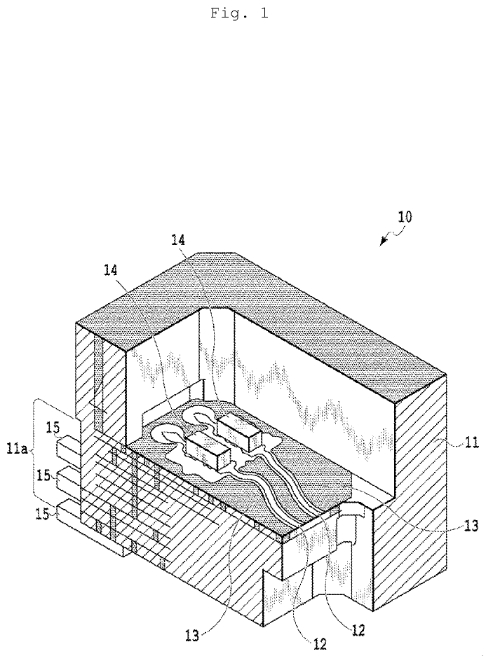

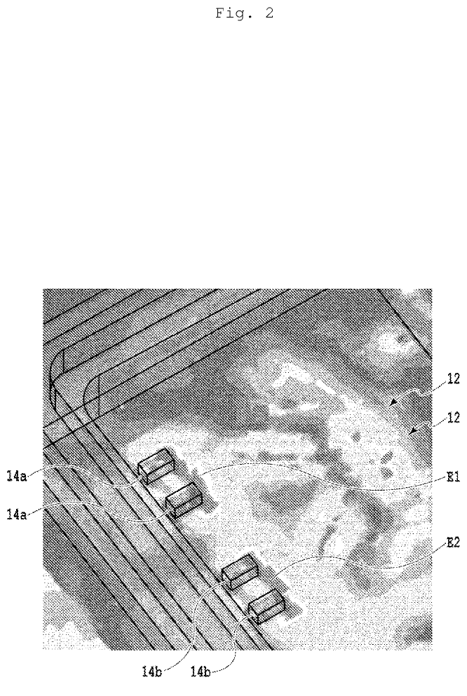

In each of the modes in FIGS. 7 to 9, a line form of a structure (GSSG structure) in which the GND electrode 23 is absent between the two RF wires 22 serving as the differential lines is illustrated. However, as in the case of the ICR 10 illustrated in FIG. 1, a line form of a structure (GSGSG) in which the GND electrodes 23 are interposed between the two RF wires 22 can also be used instead. Therefore, the optical communication component of the present invention is not limited to the configuration disclosed in each of the embodiments.

Note that, in the exemplified structure of the COSA 20C according to the second embodiment also, the separation projecting portion 27b separately defines the region where the DC block capacitor 24a is present. However, in the COSA 20C, the conductive pattern provided on the package 21A also differs depending on a mode of each of the various devices mounted on the upper surface of the package 21A. Accordingly, it is possible to provide the COSA 20C with a structure in which, in the same manner as described in the first embodiment, an additional separation projecting portion is provided to separately define even the region where the DC block capacitor 24b is present. In other words, the number of the separation projecting portions are to be disposed and places where the separation projecting portions are to be disposed can freely be changed depending on various devices mounted on the package 21A and the conductive pattern for connection thereof.

1. An optical communication component comprising:
a package having a flat plate shape;
an optical communication element mounted on an upper surface of the package;
an electronic circuit element mounted on the upper surface of the package and located at a position different from that of the optical communication element;
a direct-current block device mounted on the upper surface of the package and located at a position different from those of the optical communication element and the electronic circuit element to cut off a direct-current signal included in a high-frequency signal transmitted to the electronic circuit element via a conductive pattern provided on the package; and
a lid provided over an upper portion of the package to cover the optical communication element, the electronic circuit element, and the direct-current block device,
the lid having a separation projecting portion that projects toward the upper surface of the package to separately define a region where the direct-current block device is present and a region where the optical communication element and the electronic circuit element are present.

2. The optical communication component according to claim 1, wherein the lid is at a ground potential.

3. The optical communication component according to claim 1, wherein the conductive pattern on the package includes RF wires placed to connect, as a whole, the direct-current block device, the electronic circuit element, and the optical communication element such that the direct-current block device is interposed between the RF wires.

4. The optical communication component according to claim 3, wherein a portion of each of the RF wires has a wiring structure in which the portion of the RF wire temporarily extends into an inner layer of the package via one metal via wire and then returns again to a surface layer via another metal via wire at another position.

5. The optical communication component according to claim 4, wherein
a ground electrode is provided in a surface layer of the metal via wire and
the ground electrode is electrically connected to a tip surface of the separation projecting portion of the lid.

6. The optical communication component according to claim 5, wherein the ground electrode and the tip surface of the separation projecting portion of the lid are maintained in an electrically connected state by adhesive fixation using an adhesive.

7. The optical communication component according to claim 6, wherein the adhesive is a non-conductive adhesive adhesively fixing a side wall of the separation projecting portion in the vicinity of the tip surface thereof to a top surface of the package or a conductive adhesive adhesively fixing the ground electrode to the tip surface of the separation projecting portion.

8. An optical communication component according to claim 1, wherein
a material of the lid is a metal material having a high thermal conductivity and a material of the package has a thermal expansion coefficient close to that of a printed circuit board serving as a connection partner.
